(19) United States
(12) Patent Application Publication
(10) Pub. No.: US 2024/0247379 A1
(43) Pub. Date: Jul. 25, 2024

(54) FORMATION OF METALLIC FILMS ON ELECTROLESS METAL PLATING OF SURFACES

(71) Applicant: Applied Materials, Inc., Santa Clara, CA (US)

(72) Inventors: Chao Liu, San Jose, CA (US); David John Jorgensen, Mountain View, CA (US); Marc Shull, Los Gatos, CA (US); Christopher Laurent Beaudry, San Jose, CA (US); Joseph Frederick Behnke, San Jose, CA (US)

(21) Appl. No.: 18/099,846

(22) Filed: Jan. 20, 2023

(51) Int. Cl. C23C 28/00

(52) U.S. Cl. CPC C23C 28/323; C23C 28/34

(57) ABSTRACT

Embodiments of the disclosure relate to articles, coated chamber components, and techniques of coating chamber components and systems. In particular, disclosed is a chamber component and methods of forming the chamber component that includes a substrate and a first layer disposed on the substrate, the first layer including a metal with a first atomic concentration. The chamber component further includes a second layer disposed on the first layer, the second layer including the metal with a second atomic concentration that is at least 5 percent higher than the first atomic concentration.

### TECHNICAL FIELD

Embodiments of the present disclosure relate to erosion-resistant coated articles, coated chamber components and methods of forming and using such coated articles and chamber components.

### BACKGROUND

Various semiconductor manufacturing processes use high temperatures, high energy plasma (e.g., remote and direct fluorine plasma such as NF₃, CF₄, and the like), a mixture of corrosive gases, corrosive cleaning chemistries (e.g., hydrofluoric acid) and combinations thereof. These extreme conditions may result in a reaction between materials of components within the chamber and the plasma or corrosive gases to form metal fluorides, particles, other trace metal contaminates and high vapor pressure gases (e.g., AlFₓ). Such gases may readily sublime and deposit on other components within the chamber. During a subsequent process step, the deposited material may release from the other components as particles and fall onto the wafer causing defects. Additional issues caused by such reactions include deposition rate drift, etch rate drift, compromised film uniformity, and compromised etch uniformity. It is beneficial to reduce these defects with a stable, non-reactive coating on the reactive materials to limit the sublimation and/or formation of particles and metal contaminants on components within the chamber.

### SUMMARY

Disclosed herein, according to one embodiment, is a chamber component for a processing chamber that includes a substrate, and a first layer disposed on the substrate, the first layer comprising a metal with a first atomic concentration, and a second layer disposed on the first layer, the second layer comprising the metal with a second atomic concentration that is at least 5 percent higher than the first atomic concentration.

In another embodiment, disclosed herein is a method for maintaining a plasma environment at a temperature that exceeds 250 degrees Celsius, the plasma environment including fluorine radicals, and exposing a layered structure to the plasma environment. The layered structure includes a substrate, and a first layer disposed on the substrate, the first layer comprising a metal with a first atomic concentration below 90 percent.

In yet another embodiment, disclosed is a processing chamber that includes a chamber component, the chamber component including a substrate, and a first layer disposed on the substrate, the first layer including a metal with a first atomic concentration. The chamber component further includes a second layer disposed on the first layer, the second layer including the metal with a second atomic concentration that is at least 5 percent higher than the first atomic concentration.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a sectional view of a semiconductor processing chamber having one or more chamber components that are coated with an electroless metal plated coating having a layer of a pure (or nearly pure) metal, in accordance with some embodiments.

FIG. 2A depicts a cross-sectional view of an article having an electroless metal plated coating modified with a layer of a pure (or nearly pure) metal thereon, in accordance with some embodiments.

FIG. 2B depicts a cross-sectional view of another article having an electroless metal plated coating with a layer of a pure (or nearly pure) metal and a layer of a metal fluoride coating formed thereon, in accordance with some embodiments.

FIG. 3 is an example illustration of a processing system capable of modifying an electroless metal plated coating with a layer of a pure (or nearly pure) metal, in accordance with some embodiments.

FIGS. 4A-4C show example images of stacks of coating layers formed on a substrate, including electroless nickel plated coating layer, a pure (or nearly pure) nickel layer, and a nickel fluoride coating layer, in some embodiments. Transmission electron microscopy images show a stack of coating layers for which processing of an electroless nickel plated coating with fluorine radicals occurred at temperature 250° C. (FIG. 4A), 300° C. (FIG. 4B), and 350° C. (FIG. 4C).

FIG. 5 is a schematic illustration of an example process of manufacturing a stack of coating layers that is formed on a substrate and includes an electroless metal plated coating layer, a pure (or nearly pure) metal layer, and a metal fluoride coating layer, in accordance with some embodiments.

FIG. 6 illustrates an example method of forming pure (or nearly pure) metal layers from electroless metal plated coatings using fluorine radicals, in accordance with some embodiments.

### DETAILED DESCRIPTION

Embodiments disclosed herein describe coated articles, coated chamber components, methods of coating articles and chamber components, methods of reducing or eliminating particles from semiconductor processing chambers, methods of using coated articles and chamber components and processing chambers containing coated chamber components. For example, a substrate may be coated with nickel, which is useful in high temperature applications (e.g., at temperatures higher than those required for sputtering resistance). Nickel has mechanical properties (e.g., modulus of elasticity, tensile strength, elongation, hardness, fatigue limit, etc.), that exceed those of other metals (e.g., aluminum) and alloys used in low temperature applications. Nickel may be used in applications with temperatures up to about 800° C. for bulk nickel substrates and up to about 1,000° ° C. if the substrate is ceramic.

To further reduce reactions between component materials and reactive chemicals and/or plasmas, which form metal fluorides, particles, other trace metal contaminates and/or high vapor pressure gases, a metal fluoride (e.g., nickel fluoride) coating may be formed on a surface of the component, e.g., on a nickel coating. For example, a stable metal fluoride coating may be formed by bringing the component into contact with fluorine gas at a temperature of, for example, about 100° ° C. to about 500° C. for a period of about 1 hour to about 72 hours.

The substrate of the component may be formed of a bulk metal material, a bulk ceramic material, an aluminum alloy, aluminum nitride (AlN), alumina (Al₂O₃), stainless steel, quartz, iron, cobalt, titanium, magnesium, copper, zinc, chromium or other metals and/or combinations thereof. Example substrates include, without limitation, semiconductor chamber components and/or tools positioned in an upper portion of a processing chamber (e.g., showerhead, faceplate, liner, electrostatic chuck, edge ring, blocker plate) as well as in a lower portion of a processing chamber (e.g., sleeve, lower liner, bellows, gas box). Certain semiconductor process chamber components that may be have a metal fluoride coating described herein may have portions with a high aspect ratio (e.g., a length to diameter or length to width ratio of about 1000:1, about 500:1, about 400:1, about 300:1, 200:1, 100:1, and so on), and the surface of the portion with the high aspect ratio may be coated with metal fluoride coatings described herein. In embodiments, the semiconductor process chamber component may be suitable for high temperature applications.

In some embodiments, the substrate may be coated with an electroless metal plated coating, using an electroless deposition process. For example, an electroless metal plated coating layer may be a nickel-phosphorous coating layer, which may be in an amorphous state. The electroless deposition process can form a metal plated coating directly on the surface of the substrate. The electroless metal plated coating may be contacted with fluorine to form the metal fluoride coating. An example metal fluoride coating as defined above may include NixFy. In embodiments, the coating is a converted and conformal nickel fluoride coating that improves chamber performance and has beneficial chemical, thermal, plasma and radical erosion/corrosion resistance.

Electroless metal plating of substrates, e.g., electroless nickel plating (ENP), is significantly cheaper compared with using a bulk metal, e.g., nickel. In addition, ENP has advantages over electrochemical plating, such as more uniform thickness around complex surface structures and the ability to plate inside high aspect ratio features and cover internal features. However, under certain conditions, ENP coatings protect samples to a lesser degree than a coating of pure nickel. For example, ENP-coated samples have a higher reactivity with many corrosive substances compared with pure nickel. Additionally, ENP coatings may be less resistant than pure nickel to elevated (e.g., by 200-300° C.) temperatures due to the crystallization and subsequent chemical segregation of nickel and phosphorous.

Aspects and implementations of the present disclosure address these and other challenges of the existing metal plating technology by providing for techniques that enable efficient and cost-effective coating of electroless metal plated samples with pure (or nearly pure) metal films. Ise, pure or nearly pure metal layers may be formed on electroless metal plated coatings by exposing the coatings to fluorine radicals at elevated temperature (e.g., above 250) ° ° C. for a certain time (e.g., 1-72 hours). The fluorine radicals may be generated by a remote plasma source using a variety of fluorine-rich substances (e.g., gases), such as molecular fluorine, nitrogen trifluoride, hydrogen fluoride, and/or the like. An additional protective NiₓF_{y} coating may then be applied to the pure (or nearly pure) metal.

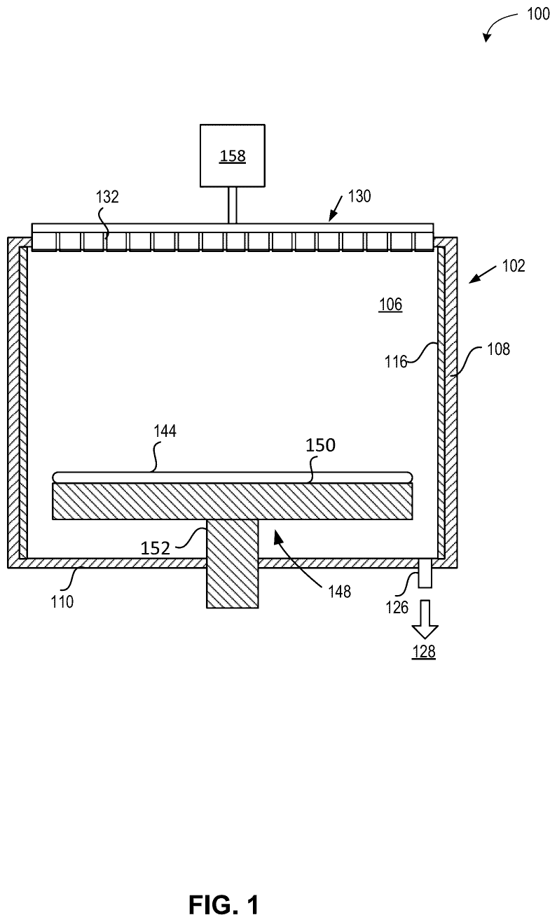

FIG. 1 is a sectional view of a semiconductor processing chamber 100 having one or more chamber components that are coated with an electroless metal plated coating having a layer of a pure (or nearly pure) metal, in accordance with some embodiments. The processing chamber 100 may be used for processes in which a corrosive plasma environment having plasma processing conditions is provided. For example, the processing chamber 100 may be a chamber for a plasma etcher or plasma etch reactor, a plasma cleaner, plasma enhanced CVD, ALD, Etch or EPI reactors and so forth. An example of a chamber component that may include an electroless metal plated coating with a layer of a pure (or nearly pure) metal is one that is at risk of exposure to fluorine chemistry and corrosive environment during processing. Such chamber components may be in the upper portion or in the lower portion of the chamber, such as a heater, electrostatic chuck, faceplate, showerhead, liner, blocker plate, gas panel, edge ring, bellow, and/or any other tool of a processing chamber. The electroless metal plated coating modified with a layer of a pure (or nearly pure) metal, e.g., as described in greater detail below, may be applied by any such chamber components.

In one embodiment, the processing chamber 100 includes a chamber body 102 and a showerhead 130 that encloses an interior volume 106. The showerhead 130 may include a showerhead base and a showerhead gas distribution plate. Alternatively, the showerhead 130 may be replaced by a lid and a nozzle in some embodiments, or by multiple pie-shaped showerhead compartments and plasma generation units in other embodiments. The chamber body 102 may be fabricated from aluminum, stainless steel, titanium, and/or any other suitable material. The chamber body 102 generally includes sidewalls 108 and a bottom 110. An outer liner 116 may be disposed adjacent to the sidewalls 108 to protect the chamber body 102.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewall 108 of the chamber body 102. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through the showerhead 130 or lid and nozzle. Showerhead 130 may be used for processing chambers used for dielectric etch (etching of dielectric materials). The showerhead 130 may include a gas distribution plate (GDP) and may have multiple gas delivery holes 132 throughout the GDP. The showerhead 130 may include the GDP bonded to an aluminum base or an anodized aluminum base. The GDP may be made from Si or SiC, or may be a ceramic such as Y₂O₃, Al₂O₃, Y₃Al₅O₁₂ (YAG), and so forth.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound comprising Y₄Al₂O₉ and a solid-solution of Y₂O₃—ZrO₂. The nozzle may also be a ceramic, such as Y₂O₃, YAG, or the ceramic compound comprising Y₄Al₂O₉ and a solid-solution of Y₂O₃—ZrO₂.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases).

A heater assembly 148 is disposed in the interior volume 106 of the processing chamber 100 below the showerhead 130 or lid. The heater assembly 148 includes a support 150 that holds a substrate 144 during processing. The support 150 is attached to the end of a shaft 152 that is coupled to the chamber body 102 via a flange. The support 150, shaft 152 and flange may be constructed of a heater material containing AlN, for example, an AlN ceramic. The support 150 may further include mesas (e.g., dimples or bumps). The support may additionally include wires, for example, tungsten wires (not shown), embedded within the heater material of the support 150. In one embodiment, the support 150 may include metallic heater and sensor layers that are sandwiched between AlN ceramic layers. Such an assembly may be sintered in a high-temperature furnace to create a monolithic assembly. The layers may include a combination of heater circuits, sensor elements, ground planes, radio frequency grids and metallic and ceramic flow channels.

An electroless metal plated coating with a layer of a pure (or nearly pure) metal in accordance with embodiments described herein may be deposited on at least a portion of a surface of any of the chamber components described herein (and those that may not be illustrated in FIG. 1), which may be exposed to processing chemistry used within the processing chamber. Example chamber components that may be protected with a layer of a pure (or nearly pure) metal described herein include, without limitation, an electrostatic chuck, a nozzle, a gas distribution plate, a shower head (e.g., 130), an electrostatic chuck component, a chamber wall (e.g., 108), a liner (e.g., 116), a liner kit, a gas line, a chamber lid, a nozzle, a single ring, a processing kit ring, edge ring, a base, a shield, a plasma screen, a flow equalizer, a cooling base, a chamber viewport, a bellow, any part of a heater assembly (including the support 150, the shaft 152, the flange), faceplate, blocker plate, and so on.

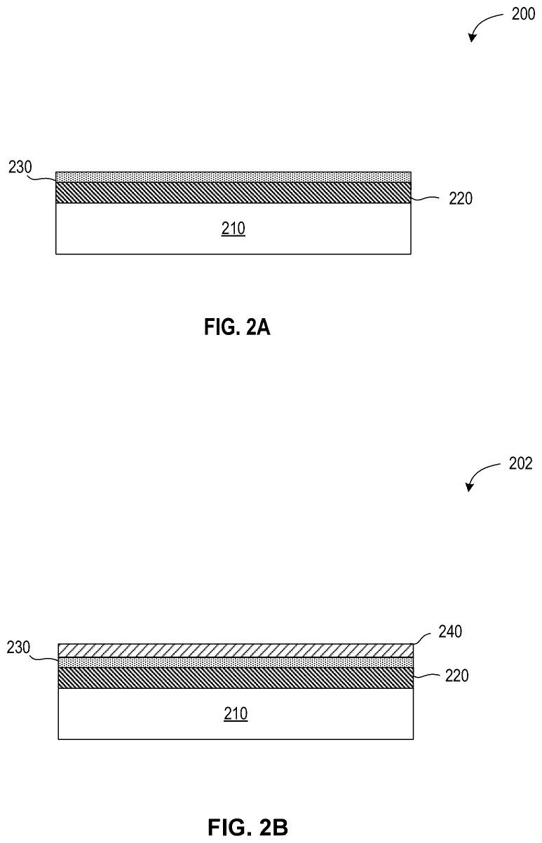

FIG. 2A depicts a cross-sectional view of an article 200 having an electroless metal plated coating modified with a layer of a pure (or nearly pure) metal thereon, in accordance with some embodiments. The article 200 may include a substrate 210 made out of a ceramic (e.g., an oxide based ceramic, a nitride based ceramic, or a carbide based ceramic), a metal (e.g., aluminum, stainless steel, titanium, and/or any other suitable metal, and/or combination thereof), or a metal alloy, quartz, or a combination thereof. Examples of oxide-based ceramics include SiO₂ (quartz), Al₂O₃, Y₂O₃, and so on. Examples of carbide-based ceramics include SiC, Si—SiC, and so on. Examples of nitride-based ceramics include AlN, SiN, and so on. In some embodiments, substrate 210 may be aluminum, anodized aluminum, an aluminum alloy (e.g., Al 6061), or an anodized aluminum alloy. In some embodiments, substrate 210 may be stainless steel, a nickel-chromium alloy, nickel, an austenitic nickel-chromium-based superalloy (e.g., Inconel R), iron, cobalt, titanium, magnesium, copper, zinc, chromium and the like. The term “substrate,” “article”, “chamber component” may be used interchangeably herein.

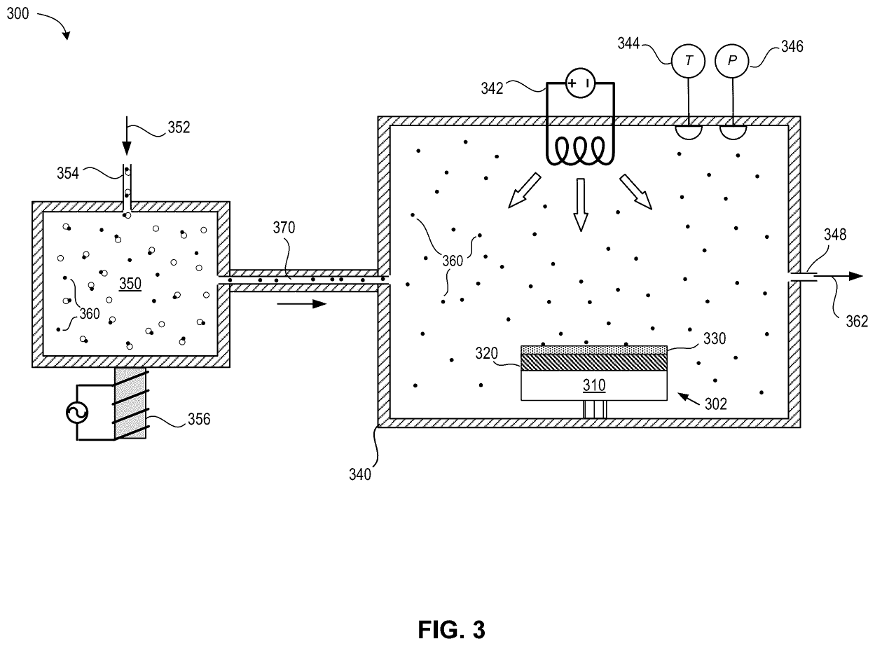

In some embodiments, as depicted in FIG. 2A, substrate 210 may include an electroless nickel plated (ENP) coating layer 220 or electroless metal plating where metal is different from nickel. Herein and below, for brevity and conciseness, a reference to ENP is often made although it should be understood that similar techniques may be used to produce a pure (or nearly pure) layer of any other metal. The ENP coating layer 220 may be formed on the article 200 to improve the performance of the article 200 in high temperature applications (e.g., at temperatures higher than those required for sputtering resistance). In some embodiments, nickel may be used due to having mechanical properties, e.g., physical properties exhibited upon application force (e.g., modulus of elasticity, tensile strength, elongation, hardness, fatigue limit, etc.), that some other metals (e.g., aluminum, other metals and alloys used in low temperature applications) might lack. The ENP coating layer 220 may be used in applications with temperatures up to about 800° C. for bulk metal substrates and up to about 1,000° ° C. if the substrate is ceramic. In embodiments, the ENP coating layer 220 may have a thickness of about 1 μm to about 50 μm, or about 5 μm to about 45 μm, or about 10 μm to about 40 μm, or about 15 μm to about 35 μm, or about 20 μm to about 30 μm, or any individual thickness or sub-range within these ranges. The ENP coating layer 220 may be contacted with a gas of fluorine radicals at an elevated temperature (e.g., as described in more detail below in conjunction with FIGS. 3-5) to remove at least some phosphorus atoms from ENP coating layer 220 and convert a portion of ENP coating layer 220 into a pure (or nearly pure) nickel layer 230. The reaction temperature, time of exposure and flow rate of the gas of fluorine radicals may be adjusted to achieve a desired (target) purity of nickel layer 230 and/or target thickness (depth) of nickel layer 230, according to embodiments herein.

In some embodiments, the thickness of pure (or nearly pure) nickel layer 230 may be between 5 nm and 1000 nm, or any sub-range of thickness or single value therein. The thickness and properties of pure (or nearly pure) nickel layer 230 described herein depend on the types and parameters of the fluorine-rich gas used to form layer 230, according to embodiments herein. These properties may be tuned and adjusted in accordance with the intended application for the coated article.

FIG. 2B depicts a cross-sectional view of another article 202 having an electroless metal plated coating with a layer of a pure (or nearly pure) metal and a layer of a metal fluoride coating formed thereon, in accordance with some embodiments. Article 202 may include substrate 210, ENP coating layer 220, and a pure (or nearly pure) nickel layer 230, e.g., substantially as described in conjunction with FIG. 2A. As depicted in FIG. 2B, at least a portion of pure (or nearly pure) nickel layer 230 may be coated with a nickel fluoride coating layer 240 according to embodiments herein. In embodiments, nickel fluoride coating layer 240 may be formed using a thermal molecular fluorine gas (F₂) conversion (Ni+F₂=NiF₂) process. The thermal molecular fluorine gas conversion process may include subjecting article 202 to pre-wet cleaning (e.g., using hydrofluoric acid, nitric acid or a combination thereof) and baking out in a thermal reactor (e.g., at a temperature of about 25° C. to about 90° C.). Article 202 (e.g., parts and/or components) to be reacted with the fluorine gas may be loaded into the reactor. The reactor may be placed under vacuum conditions, for example, at a pressure of about 10 mTorr to about 50 mTorr. Once evacuated, the temperature within the reactor may be increased to about 100° C. to about 500° C. Notably, a higher temperature may cause the nickel fluoride coating to grow (i.e., thicken) at a faster rate than at a lower temperature. When nickel fluoride coating layer 240 is formed at a temperature of about 300° C., the resulting thickness of the coating may be about 200 nm. The thickness of nickel fluoride coating layer 240 may be increased, at the same temperature, if exposed to the fluorine gas for a longer period.

Converted coatings formed by either the molecular fluorine gas process or the fluorine radical process, have an adhesive strength to the surface of the substrate of greater than about 20 mN with a 2 μm diamond stylus or 100 mN with a 10 μm diamond stylus using a Scratch Adhesion Test per ASTM C1624, D7187, G171 or other equivalent standard. The resulting converted coatings are conformal and capable of coating complex features including high aspect ratio features of the substrate (e.g., having an aspect ratio of length to diameter or length to width of about 100:1 to about 1000:1). The thickness of the resulting metal fluoride coating may be about 5 nm to about 5,000 nm, or about 10 nm to about 4,000 nm, or about 25 nm to about 3,000 nm, or about 50 nm to about 2,500 nm, or about 100 nm to about 2,000 nm, or about 250 nm to about 1,000 or any individual thickness or sub-range within these broad ranges. The coating thickness may be a function of reaction time of the fluorine gas or radicals with the surface of the coating. The resulting converted coatings may be crystalline and dense (e.g., having an approximately 0% porosity or zero porosity) and may provide better ion bombardment resistance than amorphous coatings. The metal fluoride coatings described herein provide fluorine plasma and/or radical erosion resistance as well as oxygen, hydrogen and nitrogen plasma resistance with stable properties. Because the metal fluoride coatings as described herein already contain metal fluorides and may be considered pre-saturated with fluorine. When exposed to fluorine, the metal fluoride coating absorbs fluorine like a sponge.

In embodiments, the metal fluoride coating comprises nickel fluoride and is anhydrous. The anhydrous metal fluoride coating may be non-hygroscopic, unless it is mixed with hydrated nickel fluoride. The anhydrous converted nickel fluoride coating may be crystalline and, if exposed to moisture, may retain water only by physical absorption. Notably, passivated NiF₂ at 300° C. is anhydrous, anhydrous NiF₂ is non-hygroscopic unless mixed with hydrated NiF₂, anhydrous NiF₂ forms tetragonal crystals of the rutile type, anhydrous NiF₂ exposed to moisture only take up water by physical absorption, anhydrous NiF₂ is nearly insoluble with a value of 0.02 g/100 mL, and when hydrated NiF₂ (NiF₂·4H₂O) is formed by hydroxide, nitrate or carbonate solution and reacted with HF acid, the hydrate changes to anhydrous NiF₂ at 350° C. in dry HF. NiF₂·4H₂O is a stable hydrate whereas other hydrates NiF₂·2H₂O and NiF₂·3H₂O) are non-stable. Hydrated NiF₂ (NiF₂·4H₂O) dissolves in water in 4.03 g/100 mL saturated solution.

In one example, the substrate initially may include an electroless metal plated coating on a surface of the substrate. The substrate material may be without limitation one or more of a metal, for example, aluminum, stainless steel and/or titanium, nickel, a ceramic, for example, alumina, silica and/or aluminum nitride, and/or combinations thereof. The electroless metal plated coating may be contacted with fluorine gas to convert one or more metal in the metal plated coating to a metal fluoride to form a metal fluoride coating. In embodiments, the metal fluoride coating may be a homogenous or substantially homogenous metal fluoride coating in that at least about 90%, at least about 95%, at least about 96%, at least about 97%, at least about 98%, at least about 99%, or at least about 100% of the one or more metal in the electroless metal plated coating may converted to metal fluoride.

In embodiments, nickel fluoride coating layer 240 may be characterized by a formula of NiₓF_{y}. (Correspondingly, if a metal M different from nickel is used, the formula may be MₓF_{y}). In embodiments, x may be 1, and y may range from 1 to 3. In other embodiments, nickel fluoride coating layer 240 may include NiₓP₂F_{w} (e.g., where x is 1 and z is 2) and/or NiₓAu_{z}Ag_{w}F_{y}. In embodiments, the thickness of nickel fluoride coating layer 240 may range from about 5 nm to about 5000 nm, or any sub-range of thickness or single value therein. The thickness and properties of the metal fluoride coating described herein depends on the parameters of the fluorine gas or fluorine radical conversion process according to embodiments herein. These properties may be tuned and adjusted in accordance with the intended application for the coated article.

FIG. 3 is an example illustration of a processing system 300 capable of modifying an electroless metal plated coating with a layer of a pure (or nearly pure) metal, in accordance with some embodiments. Article 302 may be placed in a process chamber, e.g., a remote plasma source (RPS) chamber 340 connected to a remote plasma source (RPS) 350. RPS 350 may receive a source gas 352 via intake 354. Source gas 352 may include a fluorine-rich gas, e.g., nitrogen fluoride NF₃, molecular fluorine F₂, hydrogen fluoride HF, Chlorine trifluoride ClF₃, etc., and a carrier gas, e.g., argon, neon, krypton, xenon, and/or other suitable low-reactive gas. In one example embodiment, source gas 352 may be delivered into RPS 350 at an example rate of 100-700 cm3/see, although it should be understood that flow rates are system-specific and can have a wide variability from system to system. In one example embodiment, source gas 352 may include 35% (e.g., by mass or partial pressure) of the fluorine-rich gas and 65% of an inert gas. In some embodiments, source gas 352 may include 20-50% (e.g., by mass or partial pressure) of the fluorine-rich gas and 50-80% of the inert gas.

RPS 350 may dissociate the fluorine-rich gas component of source gas 352 to produce fluorine radicals 360 (denoted schematically with black dots). In some embodiments, dissociation may be performed using an energy source 356, e.g., an inductive energy source or a microwave energy source supplying energy to RPS 350. Fluorine radicals 360 may be provided, over channel 370, from RPS 350 to RPS process chamber 340, where the surface of article 302 may be exposed to fluorine radicals 360. In some embodiments, article 302 may include a substrate 310 and an ENP coating layer 320. Fluorine radicals 360 may remove at least a portion of phosphorus from ENP coating layer 320, e.g., by forming one or more phosphorus fluoride compounds, e.g., PF₃, PF₅, P₂F₄, and the like. As a result, a pure (or nearly pure) nickel layer 330 may be formed at the top (as oriented in FIG. 3) of the ENP coating layer 320.

Temperature in RPS process chamber 340 may be controlled using a heating element 342 and a temperature sensor 344. The temperature may be 260° C., 270° C., 300° ° C., 320° C., 330° ° C., 350° C., 370° C., 400° ° C., 500° C., or even higher. Increasing temperature in RPS process chamber 340 may lead to increased purity of nickel layer 330, e.g., with lower temperatures (e.g., at or about 290-300° C.) resulting in a lower purity (e.g., 90-95% Ni) of nickel layer 330 and higher temperatures (e.g., 340-360° C.) resulting in higher purity (98-99.5% Ni) of nickel layer 330.

Pressure in RPS process chamber 340 may be measured using a pressure sensor 346. The pressure may be controlled by adjusting a flow rate of source gas 352 into RPS 350, a flow rate of fluorine radicals 360 from RPS 350 to RPS process chamber 340, and/or a flow of output gas 362 via exhaust 348, which may be coupled to a pump system operating similarly to a pump system 128 of FIG. 1 and may include one or more pumps and throttle valves utilized to evacuate and regulate the pressure in RPS process chamber 340. In some embodiments, the pressure in RPS process chamber 340 may be at or about 1 Torr. In some embodiments, the pressure in RPS process chamber 340 may be in the range from 0.1 Torr to 10 Torr.

Article 302 may be exposed to fluorine radicals 360 for a target time, e.g., 1 hour, 2 hours, 12 hours, 24 hours, 48 hours, 72 hours, and/or any other target time. The target time may be determined based on a target thickness of pure (or nearly pure) nickel layer 330 that is desired to be formed on the ENP coating layer 320.

After pure (or nearly pure) nickel layer 330 is formed on the ENP coating layer 320, article 302 may be removed from RPS chamber 340 and subjected to fluorine gas conversion (or any other suitable technique) to form a nickel fluoride coating on top of pure (or nearly pure) nickel layer 330. In some embodiments, article 302 may undergo fluoride gas conversion while still being inside RPS chamber 340, e.g., subject to a different reactive gas delivered over channel 370.

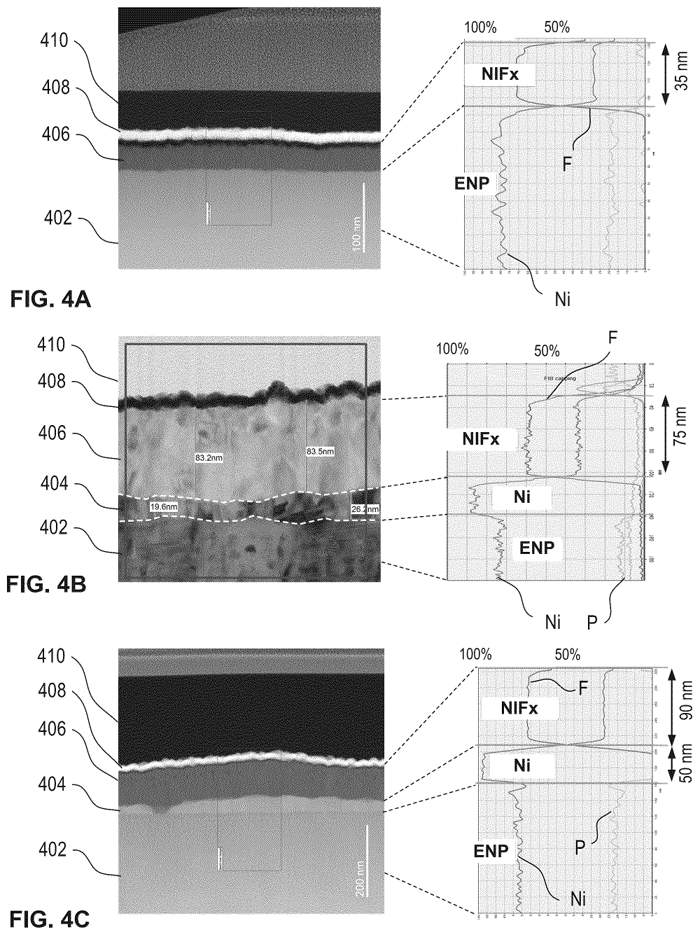

FIGS. 4A-4C show example images of stacks of coating layers formed on a substrate, including electroless nickel plated coating layer, a pure (or nearly pure) nickel layer, and a nickel fluoride coating layer, in some embodiments. The left panel in each of FIGS. 4A-4C shows a transmission electron microscopy (TEM) image of a respective example stack of coating layers and the right panel in each of FIGS. 4A-4C shows a chemical (elemental) composition of the corresponding stack obtained using an accompanying electron energy loss spectroscopy (EELS) data. The example stacks of coating layers illustrated in FIGS. 4A-4C were formed using fluorine radicals obtained by dissociation of NF₃ gas.

FIG. 4A illustrates a TEM image of a stack of coating layers for which processing of an ENP coating with fluorine radicals occurred in an environment of an RPS process chamber (e.g., a chamber that is similar to RPS chamber 340 of FIG. 3) at temperature 250° C. and pressure 1.5 Torr. The bottom layer is ENP layer 402 that is 5 μm thick (a portion of ENP layer 402 of about 150 nm is shown in the image) and is made (on average) of about 80% nickel and 20% phosphorus. The second (from the bottom) layer is a nickel fluoride layer 406 that is about 35 nm thick and is made of about 72% fluoride and 28% nickel. (An Iridium layer 408 and a carbon layer 410 are placed on the stack to facilitate TEM imaging and do not form a part of the stack of coating layers.) As illustrated in FIG. 4A, no noticeable formation of a pure (or nearly pure) nickel layer occurs under the stated conditions.

FIG. 4B illustrates a TEM image of a stack of coating layers for which processing of an ENP coating with fluorine radicals occurred in an environment of the RPS process chamber at temperature 300° C. and pressure 1.5 Torr. The ENP layer 402 is made (on average) of about 74% nickel, 12% phosphorus, 7% oxygen, 6% carbon, and traces of other elements (such as fluorine). The nearly pure nickel layer 404 is formed on top of ENP layer 402. As shown in FIG. 4B, the nearly pure nickel layer 404 is about 19-27 nm thick and is about 86% nickel, 6% oxygen, 5% carbon, and traces of other elements The nickel fluoride layer 406 formed on top of the nearly pure nickel layer 404 is about 78-84 nm thick and is about 59% fluoride and 34% nickel. (Iridium layer 408 and carbon layer 410 are placed on the stack to facilitate TEM imaging and do not form a part of the stack of coating layers.)

FIG. 4C illustrates a TEM image of a stack of coating layers for which processing of an ENP coating with fluorine radicals occurred in an environment of the RPS process chamber at temperature 350° C. and pressure X. The ENP layer 402 is made (on average) of about 78% nickel, 22% phosphorus, and traces of other elements (such as carbon). The pure (or nearly pure) nickel layer 404 is formed on top of ENP layer 402. As shown in FIG. 4C, the pure (or nearly pure) nickel layer 404 is about 50 nm thick and is about 98% nickel (with traces of other elements, such as oxygen). The nickel fluoride layer 406 formed on top of the pure (or nearly pure) nickel layer 404 is about 90 nm thick and is about 72% fluoride and 27% nickel. (Iridium layer 408 and carbon layer 410 are placed on the stack to facilitate TEM imaging and do not form a part of the stack of coating layers.)

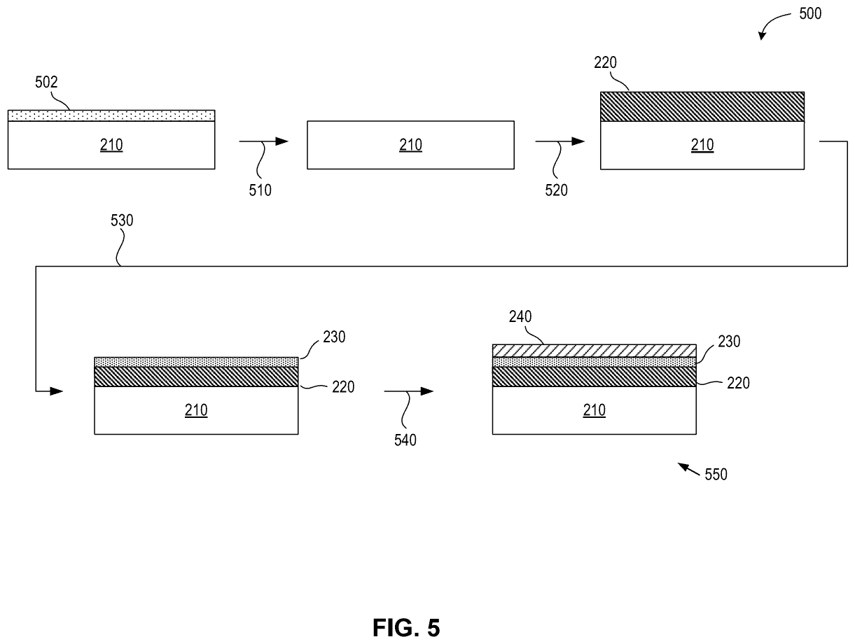

FIG. 5 is a schematic illustration of an example process 500 of manufacturing a stack of coating layers that is formed on a substrate and includes an electroless metal plated coating layer, a pure (or nearly pure) metal layer, and a metal fluoride coating layer, in accordance with some embodiments. As illustrated, a substrate 210 may have a contamination layer 502 disposed thereon. Substrate 210 may undergo a cleaning process 510 to strip the contamination layer 502 from substrate 210. Substrate 210 may be processed using electroless metal plating process 520, e.g., ENP process, to deposit ENP coating layer 220 on substrate 210. The substrate 210 with the ENP coating layer 220 may be exposed to fluorine radicals (process 530) to convert a portion (e.g., top portion) of ENP coating layer 220 into pure (or nearly pure) nickel layer 230. The fluorine gas conversion 540 may then be used to form a nickel fluoride layer 240. The resulting stack 550 includes substrate 210, ENP coating layer 220, pure (or nearly pure) nickel layer 230, and nickel fluoride layer 240.

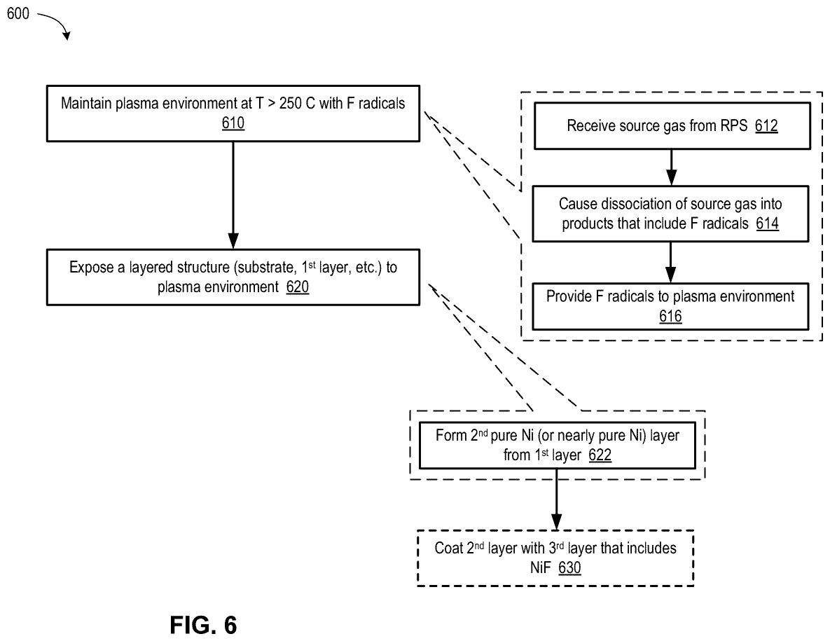

FIG. 6 illustrates an example method 600 of forming pure (or nearly pure) metal layers from electroless metal plated coatings using fluorine radicals, in accordance with some embodiments. Method 600 may be performed using the processing system 300 of FIG. 3. At block 610, method 600 may include maintaining a plasma environment at a temperature that exceeds 250 degrees Celsius The plasma environment may include fluorine radicals. In some embodiments, maintaining the plasma environment may include operations illustrated in the top callout portion of FIG. 6. More specifically, at block 612, method 600 may include receiving, by a remote plasma source, a source gas. The source gas may include a fluorine-rich gas and an inert gas. In some embodiments, the fluorine-rich may be or include at least one of nitrogen trifluoride (NF₃), molecular fluorine (F₂), or hydrogen fluoride (HF), chlorine trifluoride (ClF₃), or some other suitable gas that includes fluorine. In some embodiments, a mass fraction of the inert gas in the source gas may be between 50 percent and 80 percent, and a mass fraction of the fluorine-rich gas in the source gas may be between 20 percent and 50 percent. At block 614, method 600 may include causing dissociation of at least a part of the source gas into one or more products. The one or more products may include the fluorine radicals. At block 616, method 600 may include providing the fluorine radicals to the plasma environment.

In some embodiments, the temperature of the plasma environment may exceed 290 degrees Celsius. In some embodiments, the temperature of the plasma environment may exceed 340 degrees Celsius. In some embodiments, the plasma environment may be maintained at a pressure at or below 10 Torr.

At block 620, method 600 may continue with exposing a layered structure to the plasma environment. The layered structure may include a substrate and a first layer disposed on the substrate. In some embodiments, the first layer may include a metal with a first atomic concentration below 85 percent, below 90 percent, below 95 percent, and so on. In some embodiments, the first layer is an electroless metal plated layer. In some embodiments, the first layer is an electroless nickel plated layer. In some embodiments, the electroless metal plated layer is amorphous. In some embodiments, exposing the layered structure to the plasma environment may include operations illustrated in the bottom callout portion of FIG. 6. More specifically, at block 622, method 600 may include exposing the layered structure to the plasma environment for a predetermined time associated with formation of a second layer of a target thickness. In some embodiments, the second layer may be formed from the first layer. Forming the second layer may include removal of at least a portion of phosphorus from the first (e.g., ENP) layer with fluorine radicals. In some embodiments, the second layer may have phosphorus with atomic concentration at or below 5 percent. In some embodiments, the second layer may be free (or nearly free) of phosphorus. In some embodiments, the second layer may include nickel with a second atomic concentration at or above 90 percent, at or above 95 percent, at or above 98 percent, at or above 99 percent, at or above 99.5 percent. In some embodiments, the second atomic concentration may be at least 5 percent higher than the first atomic concentration. In some embodiments, the second layer may be or include a crystalline layer of nickel. In some embodiments, the predetermined time may be longer than one hour. In some embodiments, method 600 may further include, at block 630, coating the second layer with a third layer. For example, the third layer may include nickel fluoride NiₓF_{y} compound.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A chamber component for a processing chamber, comprising:
a substrate;
a first layer disposed on the substrate, the first layer comprising a metal with a first atomic concentration; and
a second layer disposed on the first layer, the second layer comprising the metal with a second atomic concentration that is at least 5 percent higher than the first atomic concentration.

2. The chamber component of claim 1, wherein the metal comprises nickel.

3. The chamber component of claim 1, wherein the first layer comprises an amorphous layer of electroless nickel plated layer.

4. The chamber component of claim 1, wherein the second layer comprises a crystalline layer of nickel.

5. The chamber component of claim 1, further comprising:
a third layer disposed on the second layer, wherein the third layer comprises a nickel fluoride layer.

6. The chamber component of claim 5, wherein the first layer comprises phosphorus with a atomic concentration at or above 10 percent, and wherein the second layer is free of phosphorus or comprises phosphorus with atomic concentration at or below 5 percent.

7. The chamber component of claim 1, wherein the substrate comprises at least one of aluminum alloy, aluminum nitride (AlN), alumina (Al₂O₃), nickel (Ni), stainless steel, nickel-chromium alloy, austenitic nickel-chromium-based superalloy, pure nickel, quartz, iron, cobalt, titanium, magnesium, copper, zinc, or chromium.

8. The chamber component of claim 1, wherein the second atomic concentration is at or above 95 percent.

9. The chamber component of claim 8, wherein the second atomic concentration is at or above 99 percent.

10. The chamber component of claim 1, wherein the substrate comprises a surface of a tool of a semiconductor processing chamber, and wherein the tool comprises at least one of a heater, an electrostatic chuck, a faceplate, a showerhead, a liner, a blocker plate, a gas box, an edge ring, or a bellows.

11. A method comprising:
maintaining a plasma environment at a temperature that exceeds 250 degrees Celsius, wherein the plasma environment comprises fluorine radicals; and
exposing a layered structure to the plasma environment, wherein the layered structure comprises:
a substrate, and
a first layer disposed on the substrate, the first layer comprising a metal with a first atomic concentration below 90 percent.

12. The method of claim 11, wherein maintaining the plasma environment comprises:
receiving, by a remote plasma source (RPS), a source gas, wherein the source gas comprises a fluorine-rich gas, wherein the fluorine-rich gas comprises at least one of:
nitrogen trifluoride,
molecular fluorine,
chlorine trifluoride, or
hydrogen fluoride,
causing dissociation of at least a part of the source gas into one or more products, wherein the one or more products comprise the fluorine radicals; and
providing the fluorine radicals to the plasma environment.

13. The method of claim 12, wherein the source gas further comprises an inert gas, wherein a mass fraction of the inert gas in the source gas is between 50 percent and 80 percent, and a mass fraction of the fluorine-rich gas in the source gas is between 20 percent and 50 percent.

14. The method of claim 13, wherein the temperature exceeds 290 degrees Celsius.

15. The method of claim 14, wherein the temperature exceeds 340 degrees Celsius.

16. The method of claim 11, further comprising:
maintaining the plasma environment at a pressure at or below 10 Torr.

17. The method of claim 11, wherein exposing the layered structure to the plasma environment occurs for a predetermined time, associated with formation of a second layer of a target thickness, wherein the second layer is formed from the first layer and comprises nickel with a second atomic concentration that is at least 5 percent higher than the first concentration.

18. The method of claim 17, wherein the predetermined time is longer than one hour.

19. The method of claim 17, further comprising:
coating the second layer with a third layer, wherein the third layer comprises nickel fluoride.

20. The method of claim 11, wherein the first layer comprises electroless nickel plated layer.

21. A processing chamber, comprising:
a chamber component, comprising:
a substrate; and
a first layer disposed on the substrate, the first layer comprising a metal with a first atomic concentration; and
a second layer disposed on the first layer, the second layer comprising the metal with a second atomic concentration that is at least 5 percent higher than the first atomic concentration.
